(19) United States
(12) Patent Application Publication
(10) Pub. No.: US 2012/0164344 A1
(43) Pub. Date: Jun. 28, 2012

(54) Activation of Electrode Surfaces by Means of Vacuum Deposition Techniques in a Continuous Process

(75) Inventors: Antonio Lorenzo Antozzi, Merate (LC) (IT); Andrea Francesco Gullá, Shaker Heights, OH (US); Luciano Iacopetti, Milan (IT); Gian Nicola Martelli, Vimodrone (Milan) (IT); Enrico Ramunni, San Donato Milanese (Milan) (IT); Christian Urgeghe, Segrate (Milan) (IT)

(73) Assignee: Industrie De Nora S.p.A., Milan (IT)

(21) Appl. No.: 13/413,121

(22) Filed: Mar. 6, 2012

Related U.S. Application Data
(63) Continuation of application No. PCT/EP2010/062902, filed on Sep. 2, 2010.

(30) Foreign Application Priority Data
Sep. 3, 2009 (IT) MI2009A001531

(51) Int. Cl. B05D 5/12; C23C 16/48; C23C 14/34; C23C 16/02

(52) U.S. Cl. 427/534; 427/124; 427/126.3; 204/192.1

(57) ABSTRACT

The invention relates to a method of manufacturing of metal electrodes for electrolytic applications by means of a continuous deposition of a layer of noble metals upon metal substrates by a physical vapour deposition technique.

### CROSS-REFERENCE TO RELATED APPLICATION

This application is a continuation of PCT/EP2010/062902 filed Sep. 2, 2010, that claims the benefit of the priority date of Italian Patent Application No. MI2009A001531 filed Sep. 3, 2009, the contents of which are herein incorporated by reference in their entirety.

### FIELD OF THE INVENTION

The invention relates to a method of manufacturing of catalysed electrodes for electrolytic applications.

### BACKGROUND OF THE INVENTION

The use of catalyst coated metal electrodes in electrolytic applications is known in the art. Electrodes consisting of a metal base (for instance, of titanium, zirconium or other valve metals, nickel, stainless steel, copper or alloys thereof) equipped with a coating based on noble metals or oxides thereof are, for instance, employed as hydrogen-evolving cathodes in water or alkali chloride electrolysis processes, as oxygen-evolving anodes in electrometallurgical processes of various kinds or for chlorine evolving anodes, again in alkali chloride electrolysis. Electrodes of such type can be produced thermally, by decomposition of precursor solutions of the metals to be deposited by suitable thermal treatments, by galvanic electrodeposition from suitable electrolytic baths, or again by direct metallisation, by means of flame or plasma-spray processes or by chemical or physical vapour deposition.

Vapour deposition techniques can have the advantage of allowing a more accurate control of coating deposition parameters. They are generally characterised by operating at a certain degree of vacuum, which can be higher or lower depending on the different types of application (cathodic arc deposition, pulsed laser deposition, plasma sputtering optionally ion beam-assisted and others). This implies that processes known in the art are fundamentally characterised by being batch processes, which require loading the substrate into a suitable deposition chamber, which must undergo a lengthy process of depressurisation, lasting several hours, to be able to subsequently treat a single piece. The overall treatment time can be partially reduced by equipping the vapour deposition machinery with two separated chambers, namely a conditioning chamber, wherein a moderate vacuum level is maintained (for instance 10⁻³-1 Pa) and a deposition chamber, which can be put in communication with the conditioning chamber thereby receiving the piece to be treated already at a certain vacuum degree. The deposition chamber is thus subjected to the high vacuum conditions (for instance 10⁻⁶ to 10⁻³ Pa) required to generate a high efficiency plasma, without having to start from atmospheric conditions. Vapour deposition is, nevertheless, affected by the intrinsic limitations of a batch-type process.

### SUMMARY OF THE INVENTION

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter. As provided herein, the invention comprises, under one aspect a method for the production of electrodes for electrolytic processes, comprising the depositing in continuous-type process of a compact layer of noble metals or oxides thereof on a metal substrate by means of a chemical or physical vapour deposition technique, the method comprising loading of the metal substrate in preformed pieces into a conditioning chamber of a physical vapour deposition device, depressurising of the conditioning chamber at a first pressure level; and sequential automatic execution on said preformed pieces of a cycle of loading into a deposition chamber, physical vapour deposition of the compact layer of noble metals at a second pressure level lower than the first pressure level, and sequential discharge to an extraction chamber.

In another aspect, the invention comprises a method for the production of electrodes for electrolytic processes comprising deposition in a continuous-type process of a compact layer of noble metals or oxides thereof on a metal substrate by a chemical or physical vapour deposition technique, the substrate comprising a coil of mesh or a coil of expanded sheet, wherein the physical vapour deposition device comprises an MPS or DC Plasma Sputtering device of the roll-to-roll or roll-to-sheet type and the physical vapour deposition of the compact layer of noble metals is carried out at a pressure level of abut 10⁻³ to 1 Pa. To the accomplishment of the foregoing and related ends, the following description sets forth certain illustrative aspects and implementations. These are indicative of but a few of the various ways in which one or more aspects may be employed. Other aspects, advantages, and novel features of the disclosure will become apparent from the following detailed description.

### DESCRIPTION

Several aspects of the invention are set forth in the appended claims.

In one embodiment, the invention relates to a method for manufacturing electrodes suitable for electrolytic applications, comprising a deposition of noble metals, for instance platinum, ruthenium or iridium, or of oxides thereof, onto a metal substrate by means of a chemical or physical vapour deposition technique in a continuous-type process. The continuous deposition can be carried out in a chemical or physical vapour deposition device provided with a conditioning chamber that can be operated at a modest depressurisation level, for example, at a pressure of about 10⁻³ to 1 Pa, A deposition chamber—ideally having a volume as low as possible—which in a first operative state can be put in hydraulic connection with the conditioning chamber and in a second operative state can be isolated from the conditioning chamber and subjected to a high depressurisation level, for instance about 10⁻⁶ to 10⁻³ Pa. An optional withdrawal chamber, which in a first operative state can be put in hydraulic connection with the deposition chamber and in a second operative state can be isolated from the deposition chamber, that can be operated at a depressurisation level comparable to that of the conditioning chamber.

In one embodiment, the metal substrate is loaded in the conditioning chamber of a device as hereinbefore described in preformed pieces, for instance, arranged in sheets cut in the final size of use in a series of shelves or trays of a sequential feed apparatus. The whole device is then depressurised at a moderate vacuum degree. This first depressurisation step can be carried out with the conditioning chamber, the deposition chamber and the optional withdrawal chamber in mutual hydraulic connection. In a subsequent step, the deposition chamber is isolated and subjected to a high vacuum degree. This aspect is especially important for plasma-assisted deposition processes, since it significantly increases their efficiency. Deposition processes in plasma phase are normally carried out in a dynamic vacuum. The indicated level of depressurisation (for instance 10⁻⁶ to 10⁻³ Pa) is the one required to generate high density plasma by means of different techniques (for instance by feeding a gas flow, optionally argon, across an electromagnetic field). The properly called deposition takes place by interaction of plasma with a metal target, with consequent extraction of metal ions conveyed onto the substrate to be treated, optionally with the additional assistance of electromagnetic fields, ion beams or the like. It is also possible to feed a flow containing a suitable reactant, for instance oxygen, in case one wishes to deposit the element vaporised from the target in form of oxide. Alternatively, it is possible to carry out the deposition of metal oxides starting from the vaporisation of targets comprising metal oxides, thereby simplifying the process although this normally has a negative impact on the process speed. The vaporisation of the metal or oxide and the optional injection of a gaseous reactant cause the actual degree of vacuum during the deposition step to be lower than the original one of plasma generation (typically somewhat higher than that of the conditioning chamber). Once the device, loaded with the pieces to be continuously treated, has been depressurised at the various degrees of vacuum indicated for the different chambers, the preformed pieces are subjected to a cycle of sequential feed to the deposition chamber, chemical or physical vapour deposition and subsequent discharge to the optional withdrawal chamber. The discharge of a treated piece is followed by the feeding of the subsequent substrate and the restoring of the degree of vacuum in the deposition chamber, once more isolated from the rest of the device, in considerably reduced times. For substrates of adequate shape, a direct discharge to the atmosphere can be foreseen. Smooth and thin substrates, for example, can be discharged from a slit with controlled hydraulic seal without significantly affecting the degree of vacuum in the deposition chamber.

In one embodiment, the method as hereinbefore described is used to deposit a layer of ruthenium in form of metal or oxide by means of IBAD (Ion Beam-Assisted Deposition) technique, providing the generation of plasma at a pressure of about 10⁻⁶ to 10⁻³ Pa, the extraction of ruthenium ions out of metal ruthenium targets arranged in the deposition chamber under the action of plasma assisted by an ion beam, and the consequent bombardment of the substrate to be treated with a beam containing ruthenium of energy comprised between about 1000 and 2000 eV. In one embodiment, the IBAD deposition is of dual type, that is preceded by a substrate cleaning step by bombardment with in situ-generated argon ions of lower energy level (200-500 eV). Ruthenium can also be deposited in form of metal and later converted to oxide by a subsequent thermal treatment in oxidising atmosphere, for instance with air at about 400-600° C.

In another embodiment, the deposition is carried out in a roll-to-roll or roll-to-sheet device, generally depressurised at a first degree of vacuum (for instance 10⁻³-1 Pa) and provided with a deposition section of limited volume which can be depressurised to high vacuum (10⁻³-10⁻⁶ Pa) by virtue of suitable seals. A deposition technique suited to this type of configuration is the one known as MPS (Magnetron Plasma Sputtering), providing the generation of high density plasma through the combined use of a magnetic field and an electric field of radiofrequencies. Another deposition technique fit to the scope provides the generation of high density plasma through the combined use of a magnetic field and modulated direct current (DC Plasma Sputtering).

In another embodiment, the deposition is carried out on a coil of mesh or of expanded sheet. A coil of expanded sheet fit to the scope can be obtained starting from a coil of solid sheet by a continuous process providing the unrolling, the tensioning, the mechanical expansion, an optional etching through a passage across a chemically aggressive solution and the subsequent rewinding into a coil. The etching can be useful to impart a controlled degree of roughness, suitable for the deposition process. Alternatively, the etching process can be carried out after rolling the expanded mesh back into a coil.

In another embodiment, a coil of expanded mesh is fed to a chemical or physical vapour deposition device, optionally an MPS device, suitable for roll-to-roll treatments and equipped with a section for loading and unwinding the coil, a deposition section optionally separated from the loading section by means of a first sealed slit and a rewinding section optionally separated from the deposition section by means of a second sealed slit.

In another embodiment, a coil of expanded sheet is fed to a chemical or physical vapour deposition device, optionally an MPS device, suitable for roll-to-sheet treatments and equipped with a section for loading and unwinding the coil, a deposition section optionally separated from the loading section by means of a first sealed slit and a withdrawal section optionally separated from the deposition section by means of a second sealed slit.

The withdrawal section can be integrated with a continuous cutting device in order to obtain planar electrodes of the required size. In one embodiment the deposition device operates at a pressure level of 10⁻³-1 Pa, and the deposition section operates at a dynamic vacuum obtained starting from a high vacuum level, for instance 10⁻³-10⁻⁶ Pa.

Some of the most significant results obtained by the inventors are presented in the following examples, which are not intended as a limitation of the extent of the invention.

### EXAMPLE 1

A series of 20 sheets of titanium grade 1, of 1000×500×0.89 mm size, were etched in 18% vol. HCl and degreased with acetone. The sheets were placed on respective trays of the conditioning chamber of an IBAD device for continuous manufacturing, subsequently depressurised to 130 Pa. The sheets were then sequentially fed to the deposition chamber, where they were subjected to an ionic bombardment in two steps under a dynamic vacuum with plasma generated at a pressure of 3.5.10⁻⁵ Pa. In a first step the sheets underwent an argon ion bombardment at low energy (200-500 eV), having the purpose of cleaning their surface from possible residues. In a second step, the bombardment was effected with platinum ions extracted from the plasma phase at an energy of 1000-2000 eV, with the purpose of depositing a compact coating. Upon completing the deposition of 0.3 mg/cm² of Pt, the sheets were transferred to the subsequent decompression chamber, kept at 130 Pa. At the end of the treatment on all the sheets, the decompression chamber was pressurised with ambient air before withdrawing the sheets.

From some of the thus obtained electrodes, 1 cm² samples were cut to carry out measurements of chlorine evolution potential in standard conditions, obtaining a value of 1.13 V/NHE at a current density of 3 kA/m² in NaCl solution at a concentration of 290 g/l, adjusted to pH 2 by addition of HCl, at a temperature of 50° C.

### EXAMPLE 2

A series of 10 nickel sheets of 1000×500×0.3 mm size were blasted with corundum until obtaining an R_{z} roughness value slightly below 70 μm, etched in 20% vol. HCl and degreased with acetone. The sheets were coated with a 0.1 mg/cm² ruthenium film by the IBAD process described in example 1 making use of the same device and carrying out the bombardment in the second step with ruthenium ions extracted from the plasma phase at an energy of 1000-2000 eV. After the deposition, the sheets were extracted and subjected to a thermal post-treatment in air at 400° C. for 1 hour, so as to oxidise the coated ruthenium to RuO₂. From some of the thus obtained electrodes, 1 cm² samples were cut to carry out measurements of hydrogen evolution potential in standard conditions, obtaining a value of −968 mV/NHE at a current density of 10 kA/m² in 32% by weight NaOH, at a temperature of 90° C.

### EXAMPLE 3

A coil of 20 metres of 500 mm wide and 0.36 mm thick nickel expanded mesh was thermally degreased and etched in 20% vol. HCl until obtaining an R_{z} roughness value of about 20 μm. The coil was loaded in the feed section of a Magnetron Plasma Sputtering (MPS) device for continuous roll-to-roll deposition, subjected to a pressure of 10⁻³ Pa. The device was operated at a linear speed of 0.2 cm/s. During the passage to the deposition section, the sheet was further cleaned by sputtering in pure Ar (with plasma generated at 5.10⁻⁵ Pa at a nominal power of 200 W between substrate and chamber walls and bias zero), then coated with a RuO₂ layer obtained by reactive sputtering (200 W, 20% Ar/O₂ mixture maintaining a dynamic vacuum of about 5.10⁻¹ Pa and a deposition temperature of about 450° C.). After the deposition, the expanded sheet, coated with 0.3 mg/cm² of RuO₂ corresponding to a thickness of 3 μm, was wound back into a coil in the withdrawal section from where it was extracted once the device was repressurised with ambient air. The thus-activated expanded sheet coil was then fed to a continuous cutting machine, where 100 cm long electrodes were obtained. d From some of the thus obtained electrodes, 1 cm² samples were cut to carry out measurements of hydrogen evolution potential in standard conditions, obtaining a value of −976 mV/NHE at a current density of 10 kA/m² in 32% by weight NaOH, at a temperature of 90° C.

The previous description is not intended to limit the invention, which may be used according to different embodiments without departing from the scopes thereof, and whose extent is univocally defined by the appended claims.

Throughout the description and claims of the present application, the term “comprise” and variations thereof such as “comprising” and “comprises” are not intended to exclude the presence of other elements or additives. The discussion of documents, acts, materials, devices, articles and the like is included in this specification solely for the purpose of providing a context for the present invention. It is not suggested or represented that any or all of these matters formed part of the prior art base or were common general knowledge in the field relevant to the present invention before the priority date of each claim of this application.

What we claim is:

1. Method for the production of electrodes for electrolytic processes, comprising the depositing in continuous-type process of a compact layer of noble metals or oxides thereof on a metal substrate by means of a chemical or physical vapour deposition technique, the method comprising:
loading of the metal substrate in preformed pieces into a conditioning chamber of a physical vapour deposition device;
depressurising of the conditioning chamber at a first pressure level; and
sequential automatic execution on said preformed pieces of a cycle of loading into a deposition chamber, physical vapour deposition of the compact layer of noble metals at a second pressure level lower than the first pressure level, and sequential discharge to an extraction chamber.

2. The method according to claim 1, wherein the first pressure level ranges between about 10⁻³ and about 1 Pa and the second pressure level ranges between about 10⁻⁶ and about 10⁻³ Pa.

3. The method according to claim 1, comprising a subsequent step of thermal treatment in an oxidising atmosphere.

4. The method according to claim 1, wherein the step of physical vapour deposition comprises a simultaneous oxidation of the noble metals with a gaseous reactant.

5. The method according to claim 2, wherein the physical vapour deposition device comprises an IBAD apparatus and the physical vapour deposition of the compact layer of noble metals is carried out by bombardment with ions extracted from a plasma phase with an energy of about 1000-2000 eV, preceded by a substrate cleaning step via argon ion bombardment at about 200-500 eV.

6. Method for the production of electrodes for electrolytic processes, comprising deposition in a continuous-type process of a compact layer of noble metals or oxides thereof on a metal substrate by a chemical or physical vapour deposition technique, the substrate comprising a coil of mesh or a coil of expanded sheet, wherein the physical vapour deposition device comprises an MPS or DC Plasma Sputtering device of the roll-to-roll or roll-to-sheet type and the physical vapour deposition of the compact layer of noble metals is carried out at a pressure level of abut 10⁻³ to 1 Pa.

7. The method according to claim 6, comprising a subsequent step of thermal treatment in oxidant atmosphere.

8. The method according to claim 6, wherein the physical vapour deposition comprises a simultaneous oxidation of the noble metals with a gaseous reactant.

9. The method according to claim 6, wherein the metal substrate comprises nickel, steel or titanium.

10. The method according to claim 6, wherein the noble metals or oxides thereof comprise one or more of of platinum, ruthenium, iridium and their oxides.
